(19) United States
(12) Patent Application Publication
(10) Pub. No.: US 2026/0082632 A1
(43) Pub. Date: Mar. 19, 2026

(54) ACTIVE REGION ISOLATION BETWEEN METAL GATES

(71) Applicant: Taiwan Semiconductor Manufacturing Company, Ltd., Hsin-Chu (TW)

(72) Inventors: Chih-Hung Hsieh, Hsinchu (TW); Kuo-Hua Pan, Hsinchu City (TW)

(21) Appl. No.: 18/889,649

(22) Filed: Sep. 19, 2024

(51) Int. Cl. H01L 29/423; H01L 21/8234; H01L 27/088; H01L 29/06; H01L 29/66; H01L 29/775; H01L 29/786; H10B 10/00

(52) U.S. Cl. CPC H10D 30/6735; H10B 10/12; H10D 30/014; H10D 30/43; H10D 30/6757; H10D 62/115; H10D 62/121; H10D 64/017; H10D 84/013; H10D 84/0135; H10D 84/0151; H10D 84/038; H10D 84/83

(57) ABSTRACT

One aspect of the present disclosure pertains to a device. The device includes an active region over a substrate and extending lengthwise along a first direction; an isolation structure over the substrate and surrounding the active region; first and second gate structures over the active region and extending lengthwise along a second direction perpendicular to the first direction; an interlayer dielectric (ILD) layer over the active regions; and a cut feature disposed between the first and the second gate structures and extending lengthwise along the second direction. The cut feature cuts through the ILD layer and the active region to separate the active region into two segments.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, proper isolation between active regions becomes increasingly critical. To isolate active regions, an isolation structure (e.g., a shallow trench isolation) is formed between active regions in both the x and the y directions. However, forming the isolation structures may require specific process margins that cause the end-to-end active region spacing (e.g., in the x direction) to be bigger than desired. To keep gate pitch spacing consistent, this causes edge gates to land on boundaries between an edge of an active region and an edge of the isolation structure. Due to the step-height difference between the active region and the isolation structure, the gate profile becomes distorted, which causes unpredictable variations to gate coupling.

Therefore, although existing active region isolation methods and structures have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a flow chart of a method to form a semiconductor device having a cut feature for isolating active regions between metal gates, in portion or in entirety, according to an embodiment of the present disclosure.

FIGS. 2A, 3A, 4A, 5A, 6A, 7A, 8A illustrate top views of a semiconductor device (or a portion thereof) at intermediate stages of fabrication and processed in accordance with the method of FIG. 1, according to an embodiment of the present disclosure.

FIGS. 2B, 3B, 4B, 5B, 6B, 7B, 8B illustrate cross-sectional views of a semiconductor device (or a portion thereof) cut along the lines B-B′ in respective FIGS. 2A-8A at intermediate stages of fabrication and processed in accordance with the method of FIG. 1, according to an embodiment of the present disclosure.

FIGS. 2C, 3C, 4C, 5C, 6C, 7C, 8C illustrate cross-sectional views of a semiconductor device (or a portion thereof) cut along the lines C-C′ in respective FIGS. 2A-8A at intermediate stages of fabrication and processed in accordance with the method of FIG. 1, according to an embodiment of the present disclosure.

FIG. 9 illustrates a flow chart of a method to form a semiconductor device having a cut feature for isolating active regions between metal gates, in portion or in entirety, according to another embodiment of the present disclosure.

FIG. 10 illustrates a semiconductor device processed in accordance with the method of FIG. 9, according to an embodiment of the present disclosure.

FIG. 11 illustrates a circuit diagram of an SRAM array as part of a memory device, according to an embodiment of the present disclosure.

FIG. 12 illustrates a top view device layout of an SRAM array, which may correspond in part to the circuit diagram of FIG. 11, according to an embodiment of the present disclosure.

FIG. 13 illustrates a flow chart of a method to form a semiconductor device having a cut feature for isolating active regions and for isolating gates, in portion or in entirety, according to an embodiment of the present disclosure.

FIGS. 14A, 15A, 16A, 17A, 18A, and 19A illustrate top views of a semiconductor device (or a portion thereof) at intermediate stages of fabrication and processed in accordance with the method of FIG. 13, according to an embodiment of the present disclosure.

FIGS. 14B, 15B, 16B, 17B, 18B, and 19B illustrate cross-sectional views of a semiconductor device (or a portion thereof) cut along the lines B-B′ in respective FIGS. 14A-19A at intermediate stages of fabrication and processed in accordance with the method of FIG. 13, according to an embodiment of the present disclosure.

FIGS. 14C, 15C, 16C, 17C, 18C, and 19C illustrate cross-sectional views of a semiconductor device (or a portion thereof) cut along the lines C-C′ in respective FIGS. 14A-19A at intermediate stages of fabrication and processed in accordance with the method of FIG. 13, according to an embodiment of the present disclosure.

FIGS. 14D, 15D, 16D, 17D, 18D, and 19D illustrate cross-sectional views of a semiconductor device (or a portion thereof) cut along the lines D-D′ in respective FIGS. 14A-19A at intermediate stages of fabrication and processed in accordance with the method of FIG. 13, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to semiconductor devices, and particularly to devices having cut features for isolating between ends of active regions. To prevent gate structures from landing on uneven step-height topography between edge of active regions and edge of isolation structures, dedicated cut features are formed after gate formation, and these cut features provide end-to-end active region isolation without step-height topography. In this way, the edge gate structures have smooth planar bottom surfaces to improve gate structural integrity. As described herein, instead of ends of active regions being first separated by isolation structures (which may cause step-height issues), the gate structures are first formed on planar active region surfaces, then the ends of the active regions are later defined by the cut features. By forming the cut features after forming the metal gate structures, the process margin for forming the initial isolation structures can be relaxed. This is because there is a reduced need to form isolation structures between ends of active regions. For example, isolation only needs to be formed between active regions along the y direction (gate direction) but not the x direction (active region direction). In further embodiments, the cut feature may simultaneously cut through active regions and cut through gate structures using a same patterned mask, which may apply to memory devices such as static random access memory (SRAM) devices.

To illustrate the various aspects of the present disclosure, methods of forming a semiconductor device are discussed below. Embodiments shown in the present disclosure are implemented with fin field-effect-effect transistors (FinFETs) or Gate-All-Around (GAA) field effect transistors (FETs), but the present disclosure is not limited thereto. FinFETs refer to transistors having gate stacks (gate electrodes and gate dielectric layers) that form conducting channels on three sides of a fin structure. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein. For example, the present disclosure may also be implemented with planar MOSFETs.

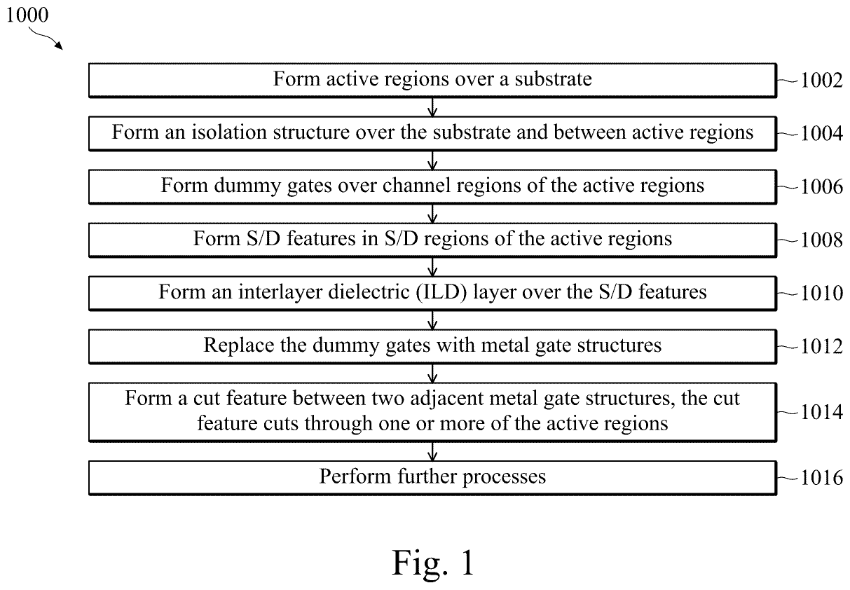

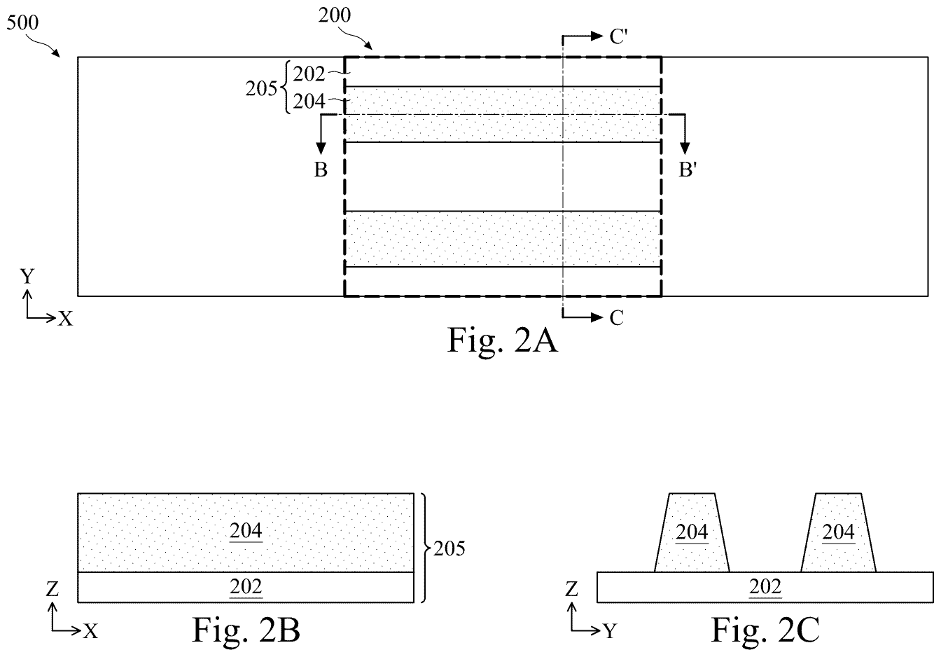

FIG. 1 illustrates a flow chart of a method 1000 to form a semiconductor device 500 (or semiconductor structure 500) having a cut feature for isolating active regions between metal gates, in portion or in entirety, according to an embodiment of the present disclosure. The method 1000 is described below with reference to FIGS. 2A-8A, 2B-8B, and 2C-8C. These figures have been simplified for the sake of clarity to better understand the inventive concepts of the present disclosure. Additional features can be added in the semiconductor device 500, and some of the features described below can be replaced, modified, or eliminated in other embodiments of the semiconductor device 500.

The semiconductor device 500 (shown in FIG. 2A) described herein may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

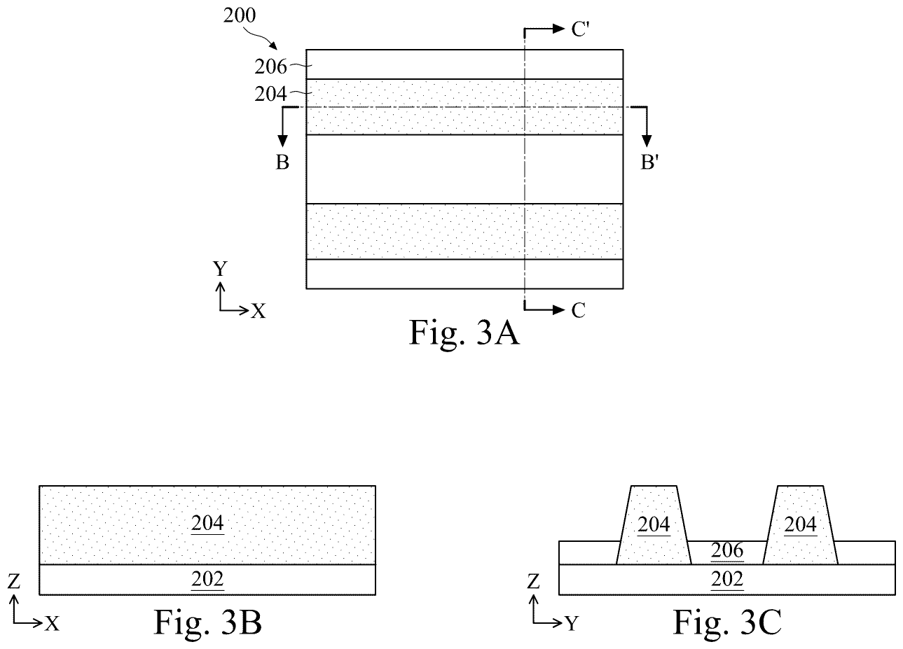

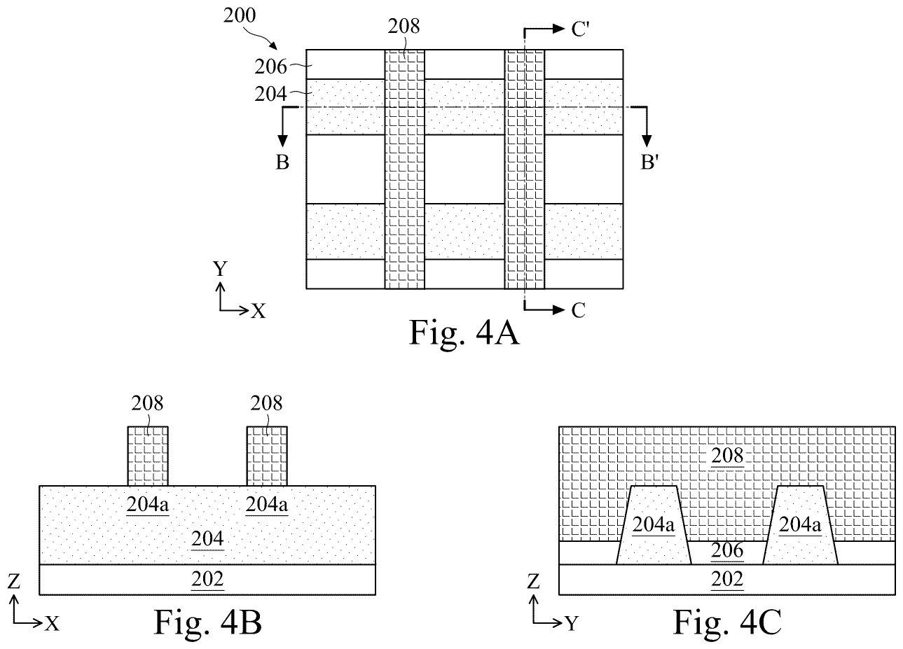

FIGS. 2A-8A illustrate top views of a semiconductor device 500 (or a portion thereof) at intermediate stages of fabrication and processed in accordance with the method 1000 of FIG. 1. FIGS. 2B-8B and 2C-8C illustrate corresponding cross-sectional views of the semiconductor device 500 in FIGS. 2A-8A, cut along the lines B-B′ and C-C′ respectively. FIGS. 2A, 2B, and 2C are at a same stage of fabrication, FIGS. 3A, 3B, and 3C are at a same stage of fabrication, FIGS. 4A, 4B, and 4C are at a same stage of fabrication, and so on.

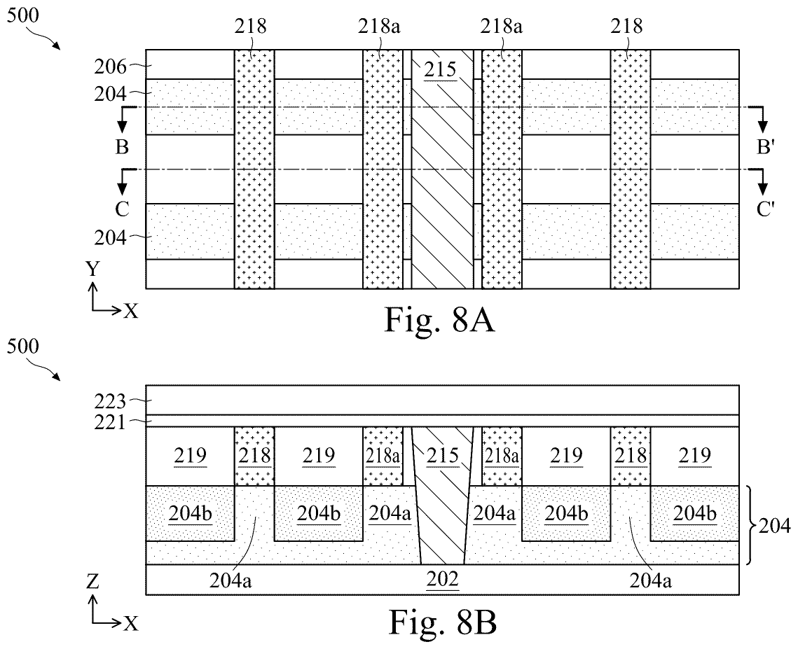

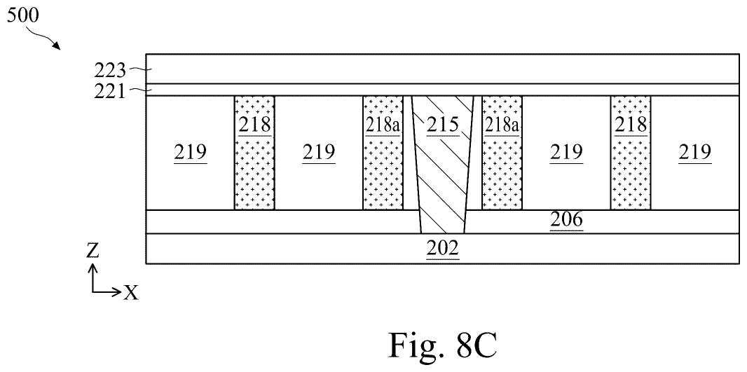

Referring now to FIG. 2A, the method 1000 begins forming the semiconductor device 500. To better understand the inventive concepts of the present disclosure, focus is turned to a target region 200 of the semiconductor device 500. The target region 200 is where the cut feature 215 will be later formed. Note that the target region 200 may be surrounded by other regions of the semiconductor device 500, and these surrounding regions are later described with respect to FIGS. 8A-8C.

Referring now to FIGS. 2A-2C collectively, the method 1000 at operation 1002 forms active regions 204 over a substrate 202. The substrate 202 may be a silicon (Si) substrate, or a substrate having other semiconductor materials such as germanium (Ge), silicon carbide (SiC), silicon germanium (SiGe), or diamond. The substrate 202 may be doped with a p-type dopant such as boron or an n-type dopant such as phosphorus. The active regions 204 protrude above the substrate 202 and may include same or similar materials as the substrate 202. The active regions 204 may be formed by patterning a base semiconductor layer 205 (or base substrate 205) to form fin-shaped active regions 204 that protrude above a top surface of the substrate 202. For example, active regions 204 may be formed by a patterning process that includes lithography and etching. In some embodiments, a lithography process forms a patterned mask layer that covers regions of the base semiconductor layer 205 for forming the active regions 204, and an etching process uses the patterned mask layer as an etch mask to etch exposed portions of the patterned mask layer. The etching process forms recesses that separate and define the active regions 204. The active regions 204 extend lengthwise along the x direction and may also be referred to as fin active regions or semiconductor fins.

Referring now to FIGS. 3A-3C collectively, the method 1000 at operation 1004 forms an isolation structure 206 over the substrate 202 and between active regions 204 along the y direction. The isolation structure 206 may be a shallow trench isolation (STI) layer and provides isolation between adjacent active regions 204 spaced along the y direction.

The isolation structure 206 may be formed by first depositing an isolation layer over the substrate 202 and the active regions 204. The isolation layer lands on a top surface of the substrate 202, fills in the recesses between the active regions 204, and lands on a top surface of the active regions 204. In other words, the isolation layer is overfilled to surround all exposed surfaces of the active regions 204. The isolation layer may be deposited by any suitable deposition process, and the isolation layer may include silicon oxide, silicon oxynitride, fluorine-doped silicate glass (FSG), a low-k dielectric, combinations thereof, and/or other suitable materials.

Thereafter, the isolation layer may be recessed to form the isolation structure 206 surrounding bottom portions (i.e., lower protruding portions) of the active regions 204. The isolation structure 206 may be formed by first performing a Chemical Mechanical Polish (CMP) to remove excess portions of the isolation layer over top surfaces of the active regions 204. The remaining portions of the isolation layer form isolation regions laterally between active regions 204. Next, the isolation regions are recessed in an etching step, so that exposed fin portions (e.g., upper protruding portions) of the active regions 204 are over the top surfaces of the isolation regions. The resulting isolation regions form the isolation structure 206. In the present embodiment, the isolation structure 206 is a shallow trench isolation (STI) structure that forms a step-height profile with the active regions 204. The thickness of the isolation structure 206 is less than the height of the active regions 204.

Referring now to FIGS. 4A-4C collectively, the method 1000 at operation 1006 forms dummy gates 208 over channel regions 204a of the active regions 204. The channel regions 204a refer to portions of the active regions 204 underneath the dummy gates 208. As shown, the dummy gates 208 extend lengthwise in the y direction across one or more channel regions 204a of one or more active regions 204. The dummy gates 208 surround the top and side surfaces of the channel regions 204a. The dummy gates 208 further extends to land on the isolation structure 206. Each of the dummy gates 208 may include a dummy gate stack and gate spacers over sidewalls of the dummy gate stack (not shown). The dummy gate stack may be made of polysilicon and the gate spacers may be made of silicon oxide, silicon nitride, silicon oxycarbide, silicon oxycarbonitride, silicon carbonitride, metal nitride, or a suitable dielectric material. Although not shown, the dummy gate stacks may include various layers, such as dummy gate electrode layers, dummy gate dielectric layers, and/or dummy hard mask layers.

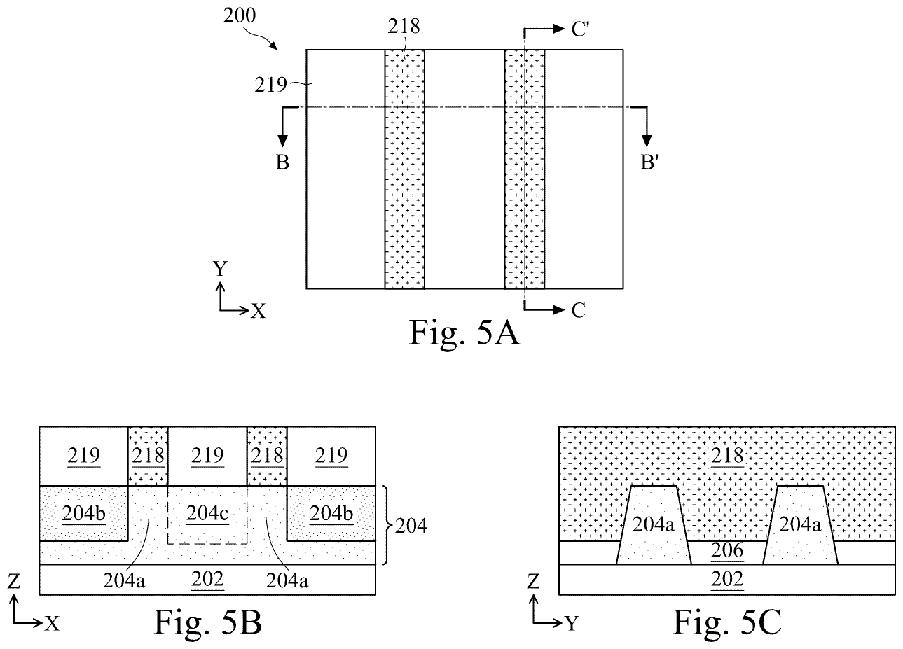

Referring now to FIGS. 5A-5C collectively, the method 1000 at operation 1008 forms source/drain (S/D) features in S/D regions 204b of the active regions 204. In the depicted embodiment, the active regions 204 include S/D regions 204b and 204c, which refer to portions of the active regions 204 adjacent the channel regions 204a and extending between the dummy gate 208. However, note that S/D features are formed in the S/D regions 204b but may or may not be formed in the S/D regions 204c. This is because the S/D regions 204c are cut regions that will be later replaced with a cut feature 215. As such, the S/D regions 204c are not used to form active transistors and thus do not need to include S/D features; they are instead used to define and separate active regions 204 in the x direction.

The S/D features may be formed by first forming S/D trenches in the S/D regions 204b. The S/D trenches expose side surfaces of the channel regions 204a by recessing top surfaces of the S/D regions 204b. The S/D trenches may be formed by a dry etching process, a wet etching process, other suitable etching process, or combinations thereof. In some embodiments, a lithography process is performed to form a patterned mask layer that covers dummy gates 208, and the etching process uses the patterned mask layer as an etch mask when forming the S/D trenches.

Thereafter, the S/D features are epitaxially grown in the S/D trenches from the recessed top surfaces of the active regions 204. The S/D features may include n-type S/D features that correspond with n-type transistor regions or p-type S/D features that correspond with p-type transistor regions. The S/D features may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the substrate 202 (or specifically the recessed S/D region 204b surrounded by the isolation structure 206). Epitaxial S/D features are doped with n-type dopants and/or p-type dopants. In some embodiments, for the n-type GAA transistors, epitaxial S/D features include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, epitaxial S/D features include silicon germanium or germanium and can be doped with boron, other p-type dopant, or combinations thereof (for example, forming Si:Ge:B epitaxial source/drain features).

Still referring to FIGS. 5A-5C collectively, the method 1000 at operation 1010 forms an interlayer dielectric (ILD) layer 219 over the S/D features in the S/D regions 204b and over the isolation structure 206 (see FIG. 8C for cross-section of ILD layer 219 over isolation structure 206). As shown in FIG. 5B (before gate replacement), the ILD layer 219 also fills the space between adjacent dummy gates 208. The ILD layer 219 may be formed by a deposition process (such as CVD, PVD, ALD, HDPCVD, MOCVD, RPCVD, PECVD, LPCVD, ALCVD, APCVD, plating, other suitable methods, or combinations thereof). In some embodiments, ILD layer 219 is formed by a flowable CVD (FCVD) process that includes, for example, depositing a flowable material (such as a liquid compound) over the device 500 and converting the flowable material to a solid material by a suitable technique, such as thermal annealing and/or ultraviolet radiation treating.

The ILD layer 219 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. ILD layer 219 can include a multilayer structure having multiple dielectric materials. In an embodiment, the ILD layer 219 includes a different dielectric material from the isolation structure 206. For example, the ILD layer 219 includes a low-k dielectric (i.e., material with dielectric constant lower than silicon oxide), and the isolation structure 206 includes silicon oxide, or vice versa. In some embodiments, a contact etch-stop layer (CESL) (not shown) is disposed between ILD layer 219 and the isolation structure 206, S/D features, and gate spacers. The CESL includes a material different than ILD layer 219, such as a dielectric material that is different than the dielectric material of ILD layer 219. For example, where ILD layer 219 includes silicon oxide or a low-k dielectric material, the CESL includes silicon and nitrogen, such as silicon nitride or silicon oxynitride. Subsequent to the deposition of ILD layer 219 and/or the CESL, a CMP process and/or other planarization process may be performed until reaching (exposing) a top portion (or top surface) of dummy gates 208. The top surface of ILD layer 219 may be substantially level with the top surface of dummy gates 208.

Still referring to FIGS. 5A-5C collectively, the method 1000 at operation 1012 replaces the dummy gates 208 with metal gate structures 218. First, the operation 1012 removes the dummy gate stacks in the dummy gates 208 to expose the channel regions 204a under the dummy gate stacks. The dummy gate stacks are removed by a suitable etching process, thereby resulting in gate trenches (not shown). The etching process is designed with etchant to selectively remove the dummy gate stacks. In the depicted embodiment, an etching process completely removes dummy gate stacks to expose top and side surfaces of the channel regions 204a in the y-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks, such as dummy gate electrode layers, dummy gate dielectric layers, and/or dummy hard mask layers. In some embodiments, the etching process is configured to selectively etch dummy gate stacks with minimal (to no) etching of other features of the device 500, such as ILD layer 219 and gate spacers adjacent the dummy gate stacks. In some embodiments, a lithography process is performed to form a patterned mask layer that covers ILD layer 219 and/or the gate spacers, and the etching process uses the patterned mask layer as an etch mask.

Thereafter, the operation 1012 forms metal gate structures 218 over the channel regions 204a and wrapping around each of the top and side surfaces of the channel regions 204a, as shown in FIG. 5C. Although not shown, each of the metal gate structures 218 may include a gate stack having a gate dielectric layer and a gate electrode disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The gate electrodes may be formed by a CVD process or a PVD process that deposits a metal fill layer that fills remaining portions of the gate trenches and over the gate dielectric layers. The metal fill layer includes a suitable conductive material, such as Al, W, and/or Cu. The metal fill layer may additionally or collectively include other metals, metal oxides, metal nitrides, other suitable materials, or combinations thereof. Alternatively, the metal fill layer is formed using another suitable deposition process, such as ALD, CVD, PVD, HDPCVD, MOCVD, RPCVD, PECVD, LPCVD, ALCVD, APCVD, spin coating, plating, other deposition process, or combinations thereof.

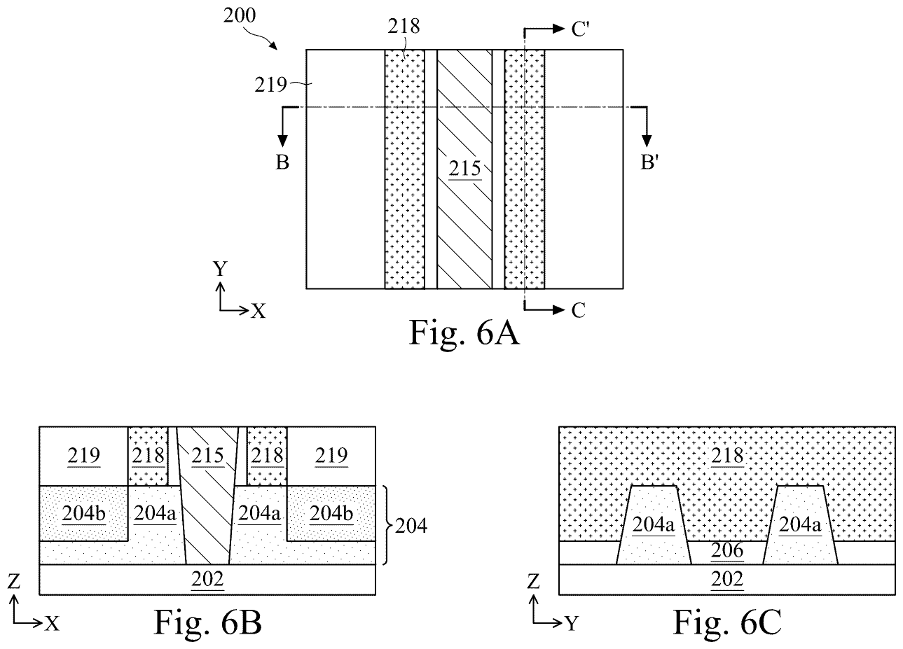

Now referring to FIGS. 6A-6C collectively, the method 1000 at operation 1014 forms a cut feature 215 between two adjacent metal gate structures 218, the cut feature 215 cuts through one or more of the active regions 204. Specifically, the cut feature 215 cuts through the S/D regions 204c to separate each of the one or more active regions 204 into two separate segments (or newly defined active regions 204). As shown, a width of the of the cut feature may be less than a width of the S/D regions 204c (i.e., portions of the S/D regions 204c may remain after forming the cut feature 215). This cut is performed between edge metal gate structures 218 such that these edge metal gate structures 218 do not form active transistor devices with the respective active regions 204 they are disposed on. Referring to FIG. 6B, the cut feature 215 penetrates through the ILD layer 219 and the active region 204 to completely isolate the active region into two segments. The cut feature 215 may land on and in some cases partially penetrate the substrate 202. In other words, the cut feature 215 may protrude into the substrate 202. As shown in FIGS. 6A-6C, the cut feature 215 has a narrowing profile from a top surface to a bottom surface due to the depth it needs to penetrate through (i.e., having tapered sidewalls). In an embodiment, the cut feature 215 has a coplanar (or substantially coplanar) top surface with top surfaces of the metal gate structures 218 and the ILD layer 219. In an embodiment, the cut feature 215 has a coplanar (or substantially coplanar) bottom surface with a top surface of the substrate 202. In an embodiment, the cut feature 215 has a coplanar (or substantially coplanar) bottom surface with a bottom surface of the isolation structure 206 (see FIG. 8C).

The cut feature 215 may be formed by first forming deep trenches (not shown) in the S/D regions 204c. The deep trenches expose side surfaces of the ILD layer 219, the active regions 204 (or specifically edge channel regions 204a), and the isolation structure 206. The deep trenches may be formed by a dry etching process, a wet etching process, other suitable etching process, or combinations thereof. In some embodiments, a lithography process is performed to form a patterned mask layer that leave the ILD layer 219 over the S/D regions 204c exposed, and the etching process uses the patterned mask layer as an etch mask when forming the deep trenches.

Thereafter, a dielectric material is deposited into the deep trenches, followed by a planarization process (e.g., CMP) to remove excess dielectric material disposed over the ILD layer 219 and the metal gates structures 218. In an embodiment, the deposited dielectric material is a same or similar material as that of the isolation structure 206. In an embodiment, the deposited dielectric material is different material as that of the isolation structure 206. For example, the deposited dielectric material is a low-k dielectric that further includes oxygen, carbon, or other materials to improve isolation. In an embodiment, the deposited dielectric material has a lower dielectric constant than that of the ILD layer 219 and the isolation structure 206. In any case, due to the cut feature 215 having a smaller volume and width dimension compared to the isolation structure 206 and the ILD layer 219, the dielectric material for the cut feature 215 may be tuned differently than that of the isolation structure 206 and/or the ILD layer 219.

As shown in FIGS. 6B and 6C, active regions 204 are separated in the x direction by the cut feature 215 and separated in the y direction by the isolation structure 206. By delegating active region isolation in the x direction to the cut feature 215 (instead of still using the isolation structure 206), the process margins for forming the isolation structure 206 is relaxed. This further avoids having the metal gate structures 218 at the edges landing on an uneven edge surface straddling the active region 204 and the isolation structure 206.

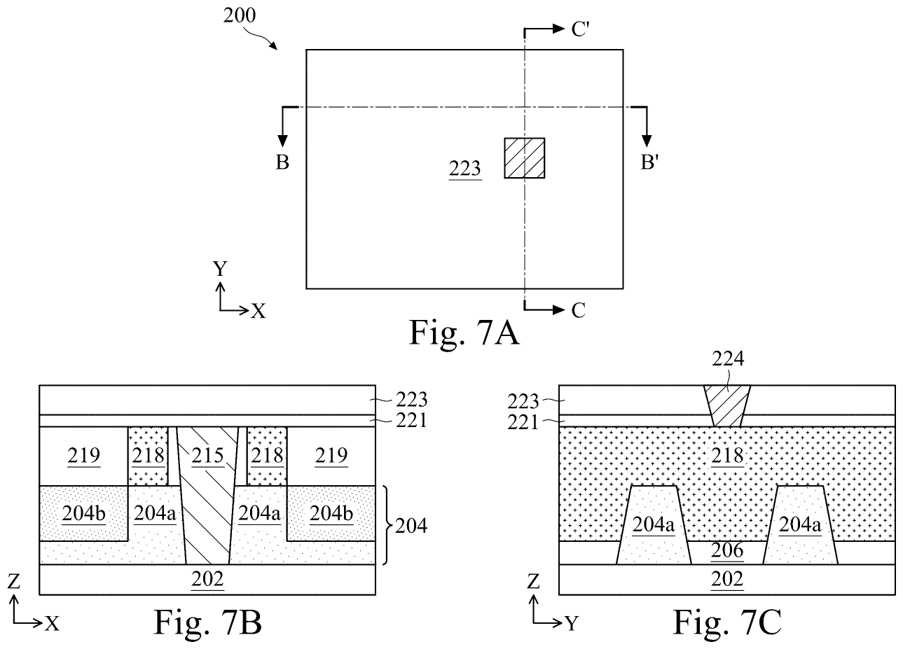

Now referring to FIGS. 7A-7C collectively, the method 1000 at operation 1016 performs further processes to continue fabrication. For example, as shown, the method 1000 at operation 1016 further forms a contact etch stop layer (CESL) 221 over the workpiece and a second ILD layer 223 over the CESL 221. In an embodiment, the CESL 221 may include silicon nitride, and the second ILD layer 223 may include the same or similar material as the ILD layer 219. As shown the CESL 221 lands on top surfaces of the ILD layer 219, metal gate structures 218, and the cut feature 215. Further shown, the operation 1016 forms a gate via 224 that lands on one of the metal gate structures 218 for gate signal routing. The gate via 224 penetrates through the second ILD layer 223 and the CESL 221. Although not shown, the operation 1016 may perform further steps to complete fabrication of the semiconductor device. For example, the method 1000 further forms S/D contacts over the S/D features in the S/D regions 204b and interconnect structures having interconnect metal lines and vias over the S/D contacts and gate vias 224. Additional operations can be provided before, during, and after method 1000. Further, some of the operations described can be moved, replaced, or eliminated for additional embodiments of method 1000.

FIGS. 8A-8C illustrate a same fabrication stage as FIGS. 7A-7C. However, FIGS. 8A-8C further shows device regions surrounding the target region 200. Note that the top view shown in FIG. 8A omits showing the ILD layer 219, the CESL 221, and the second ILD layer 223 for clearer illustration. As shown, the active regions 204 continuously extend in the x direction, and additional metal gate structures 218 are disposed over channel regions 204a of these additional metal gate structures 218. Referring to FIG. 8B, note that the metal gate structures 218 adjacent the cut feature 215 are formed over channel regions 204a that do not form transistor channels (i.e., they are dummy channel regions). As such, they do not form transistors in the active regions 204 and are referred to as edge metal gate structures 218a. However, the additional metal gate structures 218 next to these edge metal gate structures 218a do form actual transistors. These metal gate structures 218 are disposed over channel regions 204a that form transistor channels (i.e., active channel regions). These transistor channels interface and are laterally disposed between S/D features in the S/D regions 204b.

Still referring to FIG. 8B, although the edge gate structures 218 do not form transistors with the active regions 204 as shown here, these gate structures 218 may continue to extend in the y direction and form transistors with other active regions 204 (not shown). In this way, a continuous gate is formed where some portions are configured as mere metal contacts and other portions are configured as actual gates for controlling channels of transistors.

FIG. 8C illustrates a cross-section in the isolation region between the active regions 204 and across the metal gate structures 218. In this view, the ILD layer 219 is disposed over the isolation structure 206. The metal gate structures 218 extends through the ILD layer 219 to land on the isolation structure 206. And the cut feature 215 penetrates through the ILD layer 219 and the isolation structure 206 to land on the substrate 202. In the present embodiment, the cut feature 215 completely penetrates the isolation structure 206 to ensure a target active region 204 is completely cut and separate into two segments. In further embodiments, the cut feature 215 further penetrates into the substrate 202. In an embodiment, the cut feature 215 may include both an oxide and a nitride based dielectric. In an embodiment, the cut feature 215 includes different materials from the ILD layers 219 and 223 and similar materials to the isolation structure 206. In an embodiment, the cut feature 215 includes different materials from the ILD layers 219 and 223 and different materials to the isolation structure 206. In an embodiment, the cut feature 215 is spaced away from adjacent metal gate structures by about 3 nm to about 5 nm in the x direction.

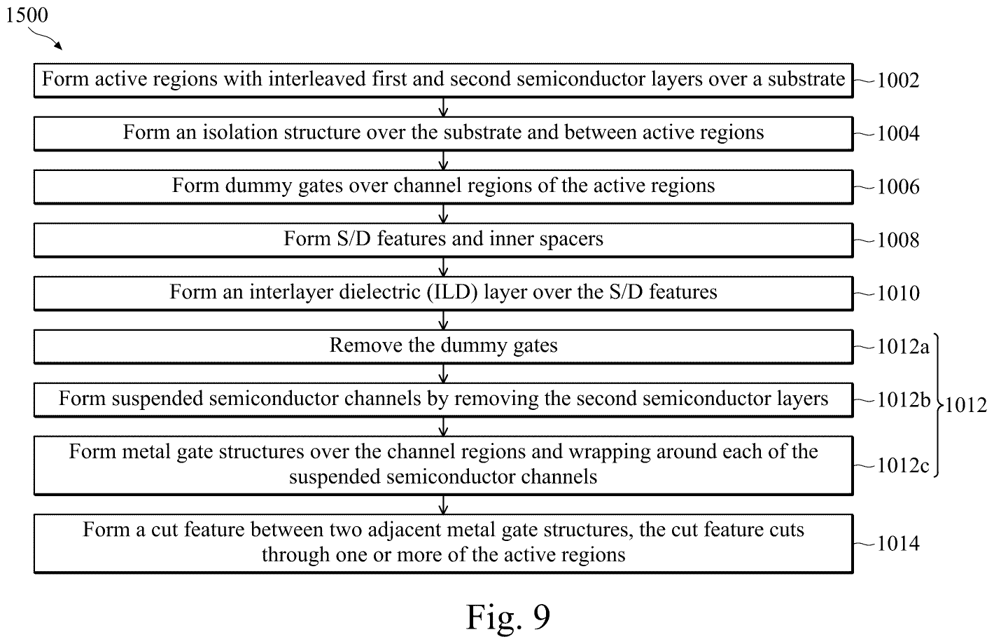

FIG. 9 illustrates a flow chart of a method 1500 to form a semiconductor device 500 having a cut feature 215 for isolating active regions 204 between metal gates, in portion or in entirety, according to another embodiment of the present disclosure. The method 1500 is similar to the method 1000, and the similar features and method steps will not be repeated for the sake of brevity. The difference is that the method 1000 is implemented for FinFET devices (i.e., the channel regions 204a are fin-shaped) while the method 1500 is implemented for GAA FET devices (i.e., the channel regions 204a include stacked transistor channels wrapped around by gate). The operation steps in method 1500 may be similar to the operation steps of method 1000 and only the differences are described below.

The method 1500 at operation 1002 form active regions 204 with interleaved first and second semiconductor layers over a substrate 202. After forming the isolation structure 206 and the dummy gates 208, the method 1500 at operation 1008 form S/D features and inner spacers. For example, after forming S/D trenches in S/D regions 204b, exposed second semiconductor layers are laterally recessed, and the gaps in the recess are filled with inner spacers (not shown). Then, the S/D features are epitaxially formed in the S/D trenches similar to the operation in method 1000. At operation 1012, dummy gates 208 are replaced with metal gate structures 218 through operation steps 1012a-1012c. At step 1012a, the dummy gates 208 are removed; at step 1012b, the remaining second semiconductor layers are removed to form suspended semiconductor channels that were formerly the first semiconductor layers (this also referred to as channel release); at step 1012c, the metal gate structures 218 are formed over the channel regions 204a and wrapping around each of the suspended semiconductor channels.

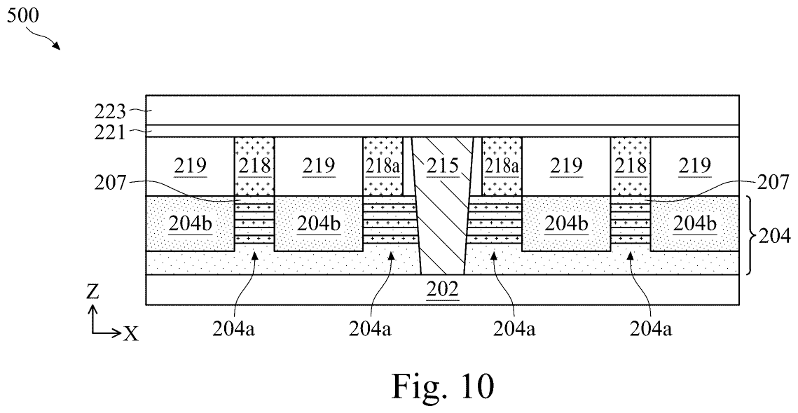

FIG. 10 illustrates an example semiconductor device 500 processed in accordance with the method 1500 of FIG. 9. As shown, the metal gate structures 218 have top portions over channel regions 204a and bottom portions wrapping around transistor channels 207. Note that although the edge metal gate structures 218a (adjacent the cut feature 215) are shown to also have bottom portions that wrap around transistor stacks of semiconductor layers, these semiconductor layers are not transistor channels 207; they may be dummy channels that are not part of an actual transistor. As shown, the cut feature 215 cuts through these dummy channels along with portions of the gate that wrap around these dummy channels. In some embodiments, these stacks of semiconductor layers (i.e., dummy channels) do not exist for edge metal gate structures 218a, and for areas under the edge metal gate structures 218a, the configuration is similar to the one shown in FIG. 8B.

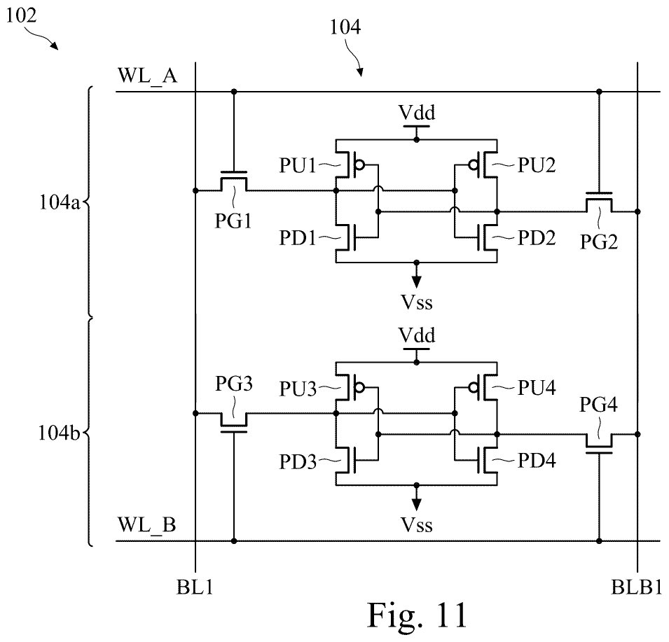

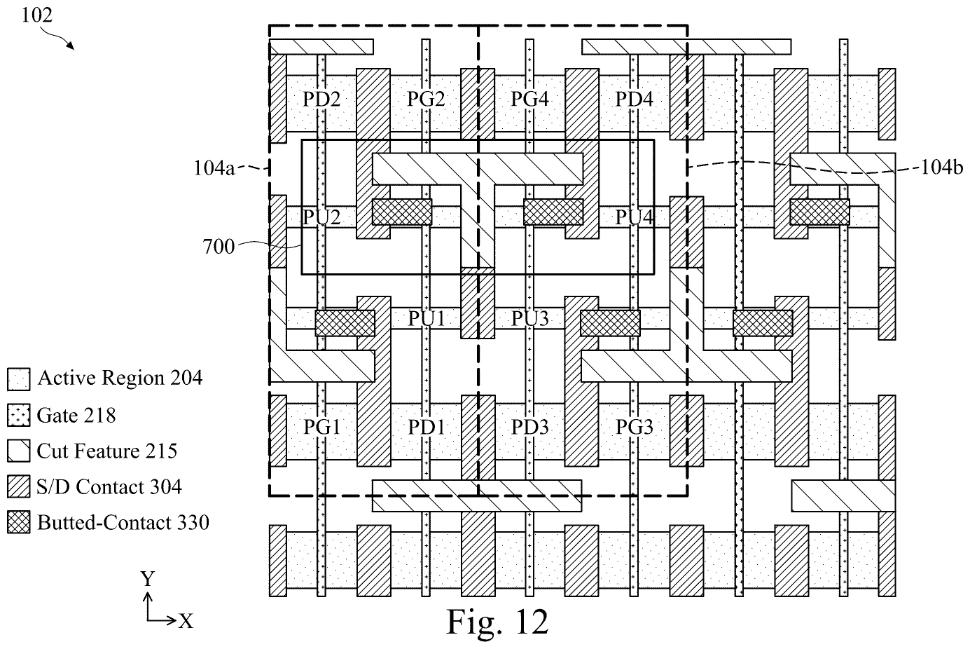

FIG. 11 illustrates a circuit diagram of a static-random-access memory (SRAM) array 102 as part of a memory device (e.g., a device 500), according to an embodiment of the present disclosure. The circuit diagram corresponds to an SRAM array 102 of two memory cells 104 (or SRAM cells 104) in a memory cell area of the memory device. The memory cells 104 are labeled SRAM cell 104a and SRAM cell 104b. Each of the SRAM cells 104a and 104b is formed of six transistors (two pull-down transistors, two pull-up transistors, and two pass-gate transistors). Each transistor is defined by a source, a drain, and a gate. Each SRAM cell 104 stores a bit of memory through the pull-down and pull-up transistors, and the SRAM cells are addressed by word lines and bit lines through the pass-gate transistors.

The SRAM cell 104a includes pull-up transistors PU1 and PU2, pull-down transistors PD1 and PD2, and pass gate transistors PG1 and PG2. The sources of PU1 and PU2 are coupled together and connected to high voltage Vdd. The sources of PD1 and PD2 are coupled together and connected to low source voltage Vss or ground. The gates of PU1 and PD1 are coupled together and connected to the common drains of PU2, PD2 and PG2. The gates of PU2 and PD 2 are coupled together and connected to the common drains of PU1, PD1, and PG1. PU1, PU2, PD1, and PD2 form a first set of cross coupled inverters to store a data bit. The source of PG1 is connected to a first bit line BL1 and the source of PG2 is connected to a first bit line bar BLB1. The gates of PG1 and PG2 are connected to a first word line WL_A.

The SRAM cell 104b includes pull-up transistors PU3 and PU4, pull-down transistors PD3 and PD4, and pass gate transistors PG3 and PG4. The sources of PU3 and PU4 are coupled together and connected to high voltage Vdd. The sources of PD3 and PD4 are coupled together and connected to low voltage Vss or ground. The gates of PU3 and PD3 are coupled together and connected to the common drains of PU4, PD4 and PG4. The gates of PU4 and PD4 are coupled together and connected to the common drains of PU3, PD3, and PG3. PU3, PU4, PD3, and PD4 form a second set of cross coupled inverters to store a data bit. The source of PG3 is connected to the same first bit line BL1 and the source of PG4 is connected to the same first bit line bar BLB1. The gates of PG3 and PG4 are connected to a second word line WL_B.

Note that FIG. 11 shows an example embodiment of an SRAM array, but other configurations may be possible. For example, in other embodiments, source and drain nodes of the different pull-up and pull-down transistors may be flipped. Further, the Vdd and Vss nodes may also be flipped. In other words, in some embodiments, high voltage Vdd may connect to source or to drain in any of the pull-up and pull-down transistors of the SRAM array. And in other embodiments, low voltage Vss or ground may connect to source or to drain in any of the pull-up and pull-down transistors of the SRAM array. As such, electrical connections to Vdd and to Vss may be referred to as power lines, power signal lines, or power line connections that provide routing to power pull-up and pull-down transistors in the memory device.

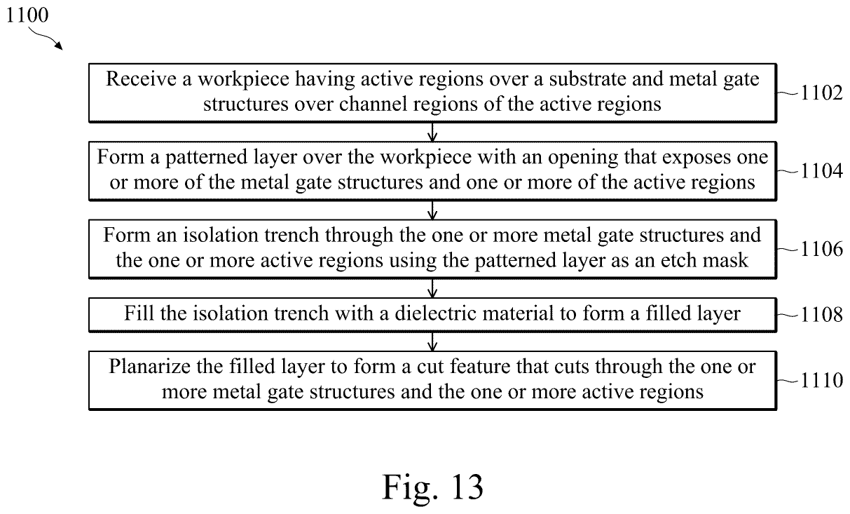

FIG. 12 illustrates a top view device layout of an SRAM array 102, which may correspond (in part) to the circuit diagram of FIG. 11. The device layout may be a layout for a device 500 (previously described) or a portion thereof. The device layout includes the SRAM cells 104a and 104b defined by dashed line cell boundaries. The SRAM cells 104a and 104b may correspond to the SRAM cells 104a and 104b in FIG. 10. The SRAM cells 104a and 104b are adjacent to each other in the x direction and mirror each other across a vertical cell boundary between them. The device layout may include additional SRAM cells 104 horizontally or vertically adjacent to the SRAM cells 104a and 104b.

FIG. 12 shows where each of the transistors PU1, PU2, PU3, PU4, PD1, PD2, PD3, PD4, PG1, PG2, PG3, and PG4 are located (labeled on the metal gate structures 218 of each transistor). How each transistor is connected to each other has already been described with respect to FIG. 11 and will not be repeated here for the sake of brevity. Note that the device layout illustrates features consistent with those described in earlier figures, and some of the similar features will not be described again for the sake of brevity.

The device layout includes several active regions 204 extending along the x direction over a base substrate (e.g., substrate 202) of the memory device (e.g., device 500). The active regions 204 may be configured for planar, fin, or gate-all-around semiconductor structures. In an embodiment, the active regions 204 are fin structures that protrude in the positive z direction from a base substrate. Some of the active regions 204 may extend lengthwise across the vertical cell boundaries so that the same active region is shared across SRAM cells 104. The active regions 204 may include n-type active regions 204 for forming pull-down and pass-gate transistors and p-type active regions 204 for forming pull-up transistors. Several metal gate structures 218 are disposed over channel regions of the active regions 204. The channel regions (or transistor channels) refer to portions of the active region directly under a metal gate structure 218. The metal gate structures 218 extend lengthwise in the y direction. Some of the metal gate structures 218 may extend across the horizontal cell boundaries to span across active regions 204 of different SRAM cells 104.

The device layout further includes S/D contacts 304 disposed over S/D regions (e.g., S/D regions 204b) of the active regions 204 to electrically connect S/D features in different active regions 204 together. For example, the S/D features may be slot contacts that extend in the y direction to couple S/D regions of different transistors together (e.g., a single S/D contact 304 routes the S/D regions of transistors PD1, PU1, and PG1 together). S/D vias (not shown) may be disposed over and lands on the S/D contacts 304. The S/D vias allow the S/D contacts 304 to electrically couple to a higher material layer in the z direction (e.g., to an interconnect structure).

The device layout further includes butted-contacts 330 for gate-to-drain electrical connections. As shown, the butted-contacts 330 couple metal gate structures 218 to S/D contacts 304. In an embodiment, the interconnection between the drain (or source) to the gate is achieved by a local interconnect (LI) technology. For example, the local interconnect is formed using the gate electrode material, such as polysilicon, metal, or other conductive material used in gate electrode. In this situation, the polysilicon (metal, or other conductive material) is used not only to form gate electrode but also to form interconnect. More particularly, the gate electrode is extended to the targeted drain (or source) region and directly lands on the targeted drain (or source) region. In another example, the butted contacts 330 are elongated contacts oriented in the x direction and are formed simultaneously with other contacts in a same procedure that includes dielectric deposition, patterning and metal deposition.

The device layout further includes cut features 215. FIG. 12 illustrates two types of cut feature 215, although three types are contemplated. A first type (not shown here) only extends in the y direction to cut through and isolate between active regions 204. This first type extends between adjacent metal gate structures 218 and is much like the cut features 215 previously described with respect to methods 1000 and 1500. A second type, and as shown, only extends in the x direction to cut through and isolate between metal gate structures 218. This second type extends between adjacent active regions 204. A third type, and as shown, extends in both the x and y directions to cut through and isolate between metal gate structures 218 and active regions 204. This third type has a T-shape, each having a first portion that cuts through metal gate structures 218 in the x direction and a second portion that cuts through active regions 204 in the y direction. The later figures describe further details of this third type of the cut feature 215 (herein referred to as a T-shaped cut feature 215), which have benefits of forming a single continuous isolation structure in a same patterning step. To better understand the features of the T-shaped cut feature 215, focus is turned to a target region 700 of the device layout. The target region 700 zooms in on a region where the T-shaped cut feature is formed.

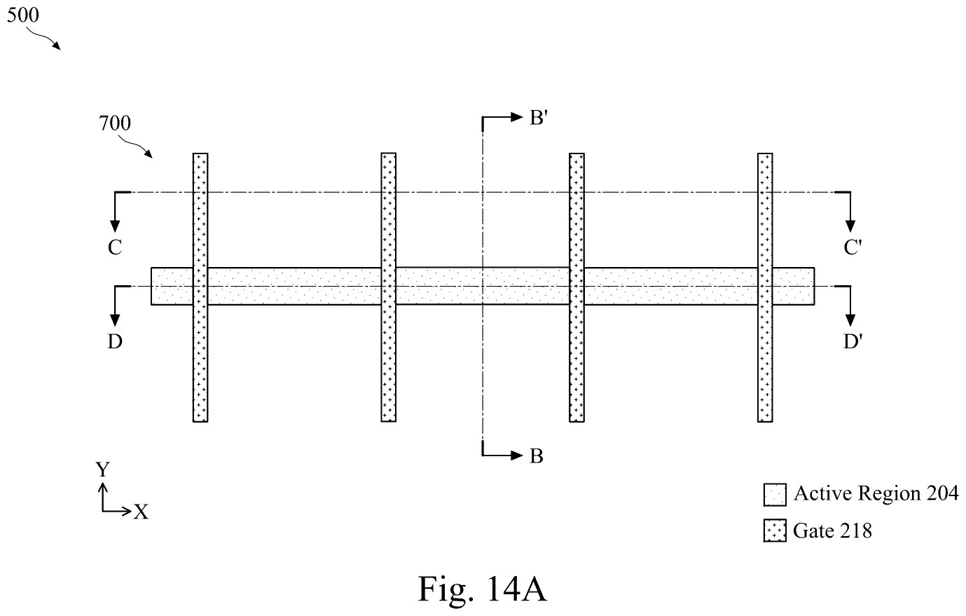

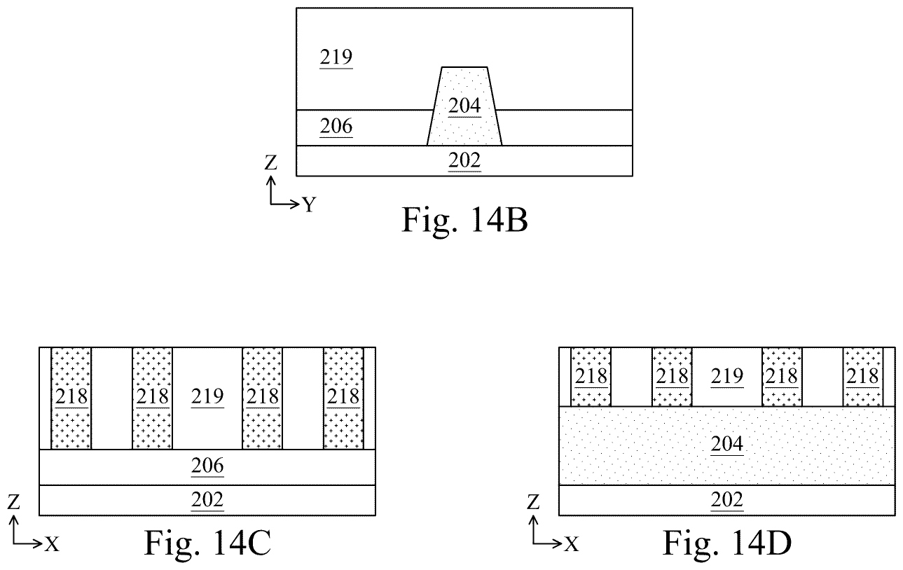

FIG. 13 illustrates a flow chart of a method 1100 to form a semiconductor device 500 having a T-shaped cut feature 215 for isolating active regions 204 and for isolating metal gate structures 218, in portion or in entirety, according to an embodiment of the present disclosure. The method 1100 is described below with reference to FIGS. 14A-19A, 14B-19B, 14C-19C, and 14D-19D, which illustrate the target region 700 where the T-shaped cut feature 215 will be formed. These figures have been simplified for the sake of clarity to better understand the inventive concepts of the present disclosure. Additional features can be added in the semiconductor device 500, and some of the features described below can be replaced, modified, or eliminated in other embodiments of the semiconductor device 500.

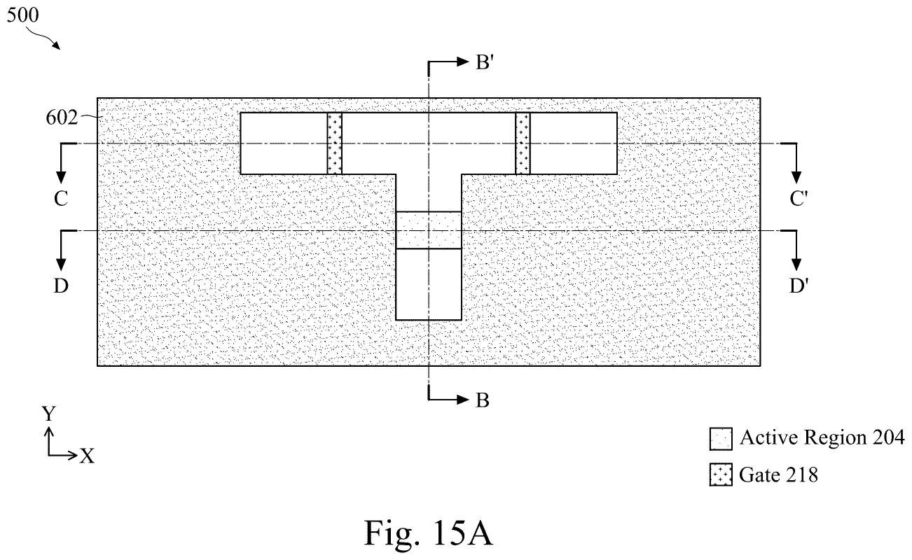

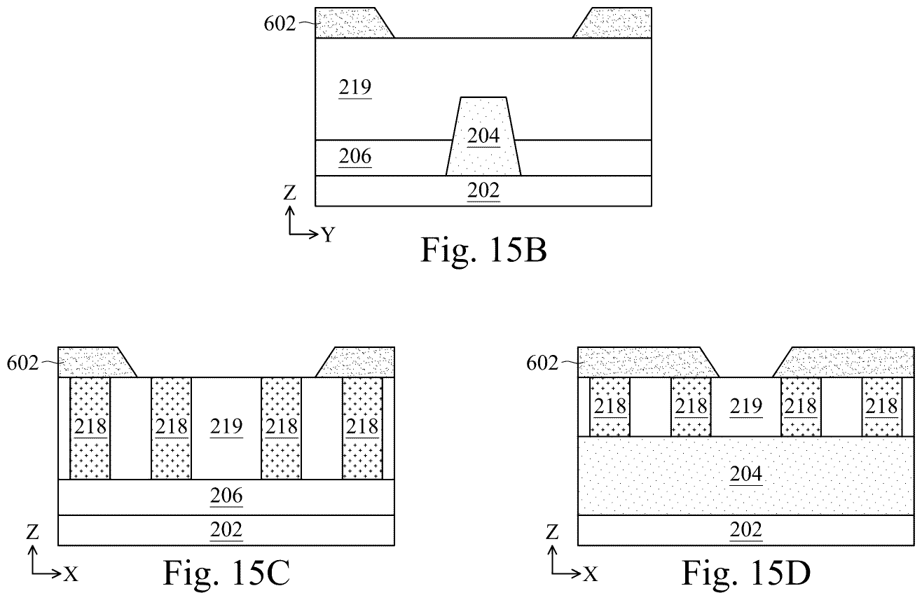

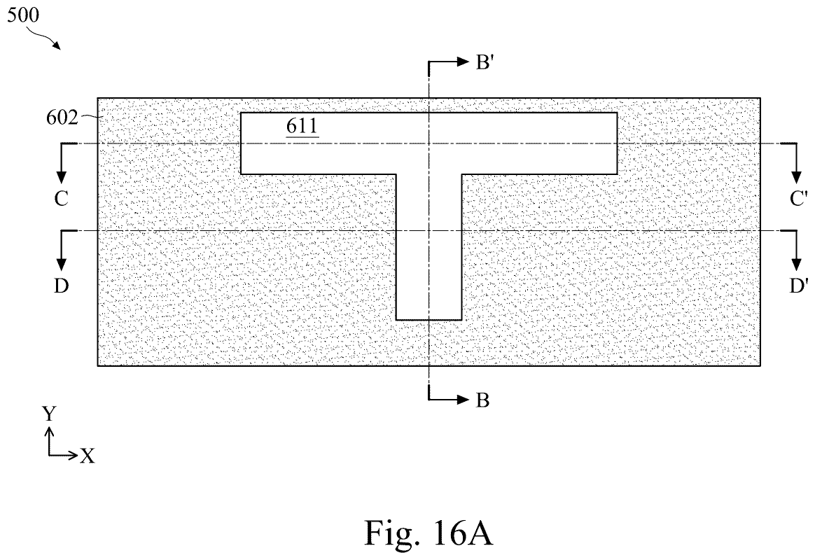

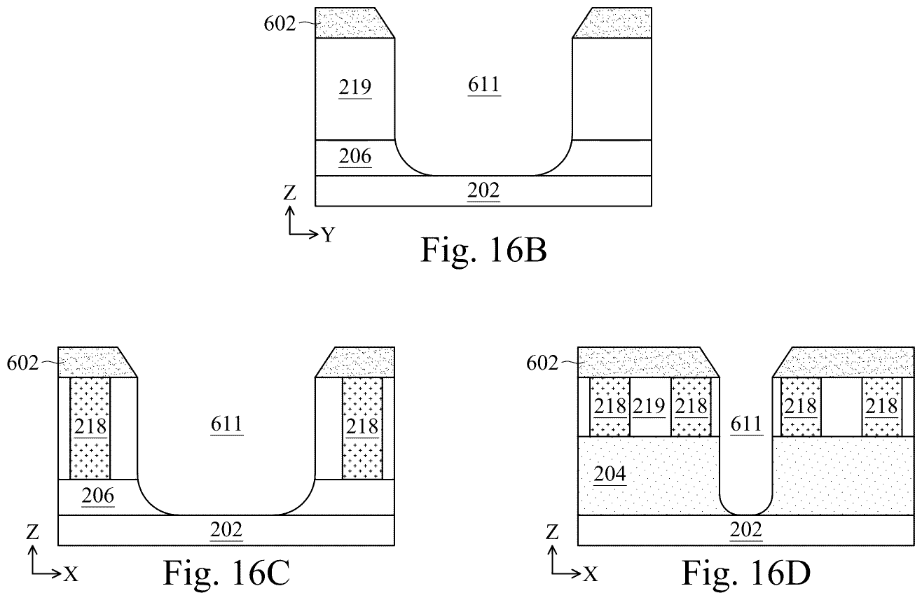

FIGS. 14A-19A illustrate top views of a semiconductor device 500 (or a portion thereof) at intermediate stages of fabrication and processed in accordance with the method 1100 of FIG. 13. FIGS. 14B-19B, 14C-19C, and 14D-19D illustrate corresponding cross-sectional views of the semiconductor device 500 in FIGS. 14A-19A, cut along the lines B-B′, C-C′, and D-D′ respectively. FIGS. 14A, 14B, 14C, and 14D are at a same stage of fabrication, FIGS. 15A, 15B, 15C, and 15D are at a same stage of fabrication, FIGS. 16A, 16B, 16C, and 16D are at a same stage of fabrication, and so on.

Referring now to FIG. 14A, the method 1100 begins forming the semiconductor device 500. The method 1100 begins at operation 1102 by receiving a workpiece having active regions 204 over a substrate 202 and metal gate structures 218 over channel regions 204a of the active regions 204. This workpiece may be formed by operations previously described in method 1000 and/or 1500. FIG. 14A illustrate four metal gate structure 218 over channel regions 204a of an active region 204. The line B-B′ cuts across a region between the middle two metal gate structures 218 where a fin cut portion of the T-shaped cut feature 215 will be formed. The line C-C′ cuts across a region having metal gate structures 218 where a gate cut portion of the T-shaped cut feature 215 will be formed. The line D-D′ cuts across the active region 204 and across where a fin-cut portion of the T-shaped cut feature 215 will be formed.

Referring now to FIGS. 14A-14D collectively, the metal gate structures 218 may be surrounded by the ILD layer 219 and land on the active region 204 and the isolation structure 206. The active regions 204 have top surfaces above the isolation structure 206, and the isolation structure 206 surrounds a bottom portion of the active regions 204. The ILD layer 219 may also surround a top portion of the active regions 204.

Referring now to FIGS. 15A-15D collectively, the method 1100 at operation 1104 forms a patterned layer 602 over the workpiece with an opening that exposes one or more of the metal gate structures 218 and one or more of the active regions 204. The patterned layer 602 may be a single mask such as a patterned photoresist layer or a hard mask patterned by a patterned photoresist layer through lithography and etching. As shown, the patterned layer 602 may expose two metal gate structures 218 over the isolation structure 206 and an active region 204 in a region between two adjacent metal gate structures 218. In the embodiment shown, the opening formed in the patterned layer 602 is a T-shaped opening, and the lengthwise openings along the x and y directions (e.g., see FIGS. 15B-15C) are greater than the widthwise openings in the x and y directions (e.g., see FIG. 15D).

Referring now to FIGS. 16A-16D collectively, the method 1100 forms an isolation trench 611 through the one or more metal gate structures 218 and the one or more active regions 204 using the patterned layer 602 as an etch mask. As shown, the lengthwise portions of the isolation trench 611 spans a greater dimension than the widthwise portions. The isolation trench 611 may be formed by any suitable etching process such as dry etching, wet etching, or combinations thereof. The etching process completely etches through a thickness of the ILD layer 219, the isolation structure 206, and the active regions 204. For example, the etching process continues until the isolation trench 611 at least exposes a top surface of the substrate 202. In this way, the method 1100 ensures the active region 204 is completely cut into two segments. If the etching only penetrates to the isolation structure 206, the metal gate structures 218 are completely cut into two segments, but the active regions 204 may not be. In an embodiment, the etching process is tuned to selectively etch dielectric materials such that the substrate 202 acts as an etch stop layer.

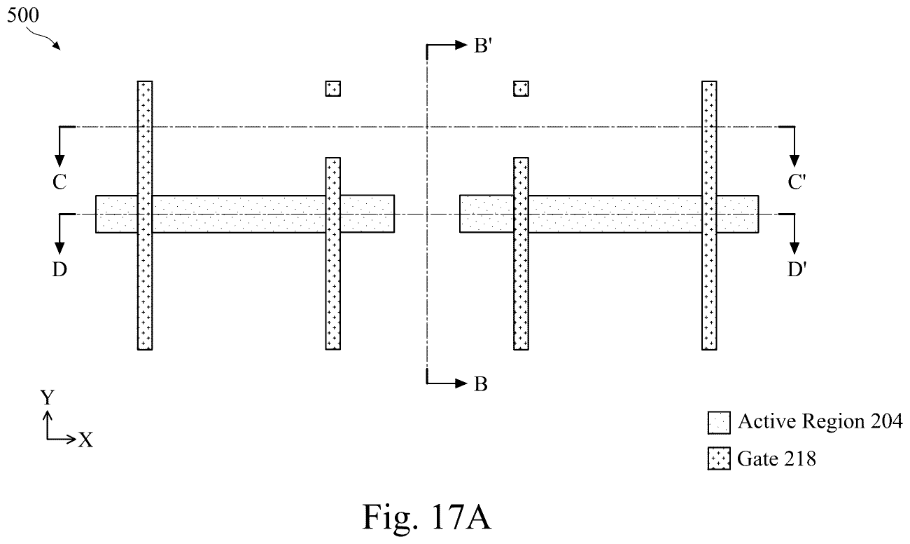

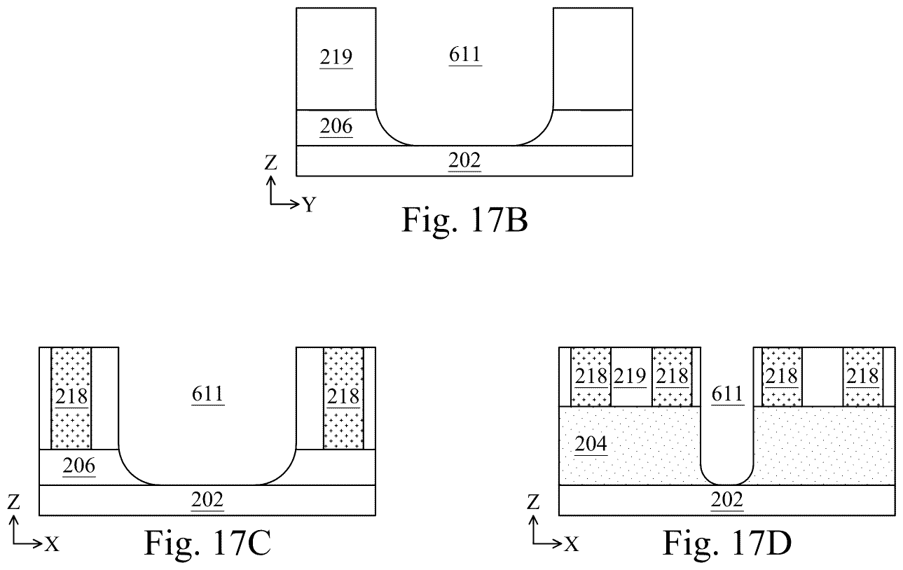

Referring now to FIGS. 17A-17D collectively, the operation 1106 may then remove the patterned layer 602 after forming the isolation trench 611. The patterned layer 602 may be removed by any suitable process such as plasma ashing, stripping, or other removal processes.

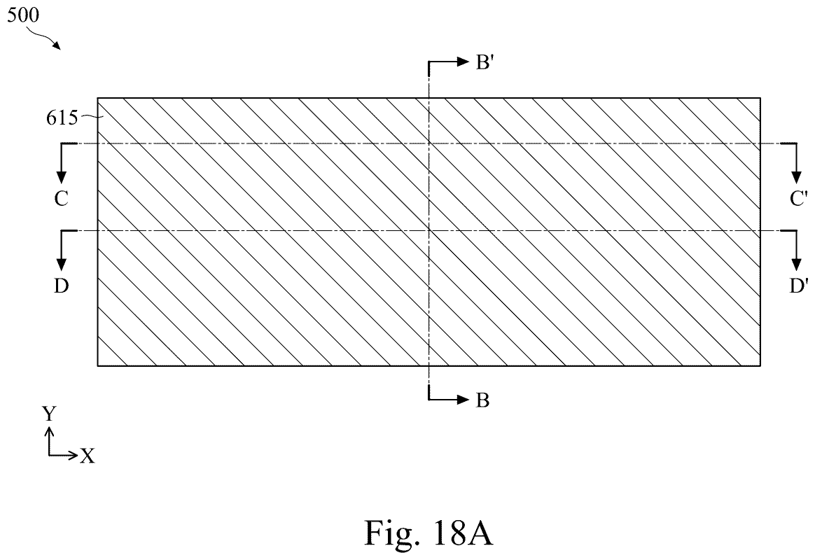

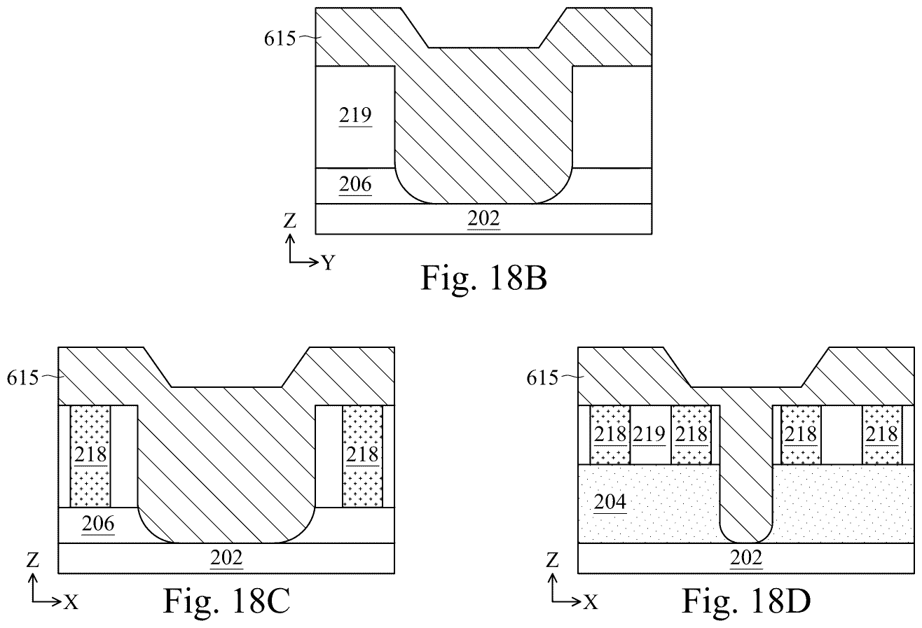

Referring now to FIGS. 18A-18D collectively, the method 1100 at operation 1108 fills the isolation trench 611 with a dielectric material to form a filled layer 615. As shown, the fill layer 615 may be deposited such that it overfills and covers top surfaces of the ILD layer 219 and the metal gate structures 218. The filled layer 615 may be deposited by any suitable deposition process, and the filled layer 615 may include silicon oxide, silicon oxynitride, fluorine-doped silicate glass (FSG), a low-k dielectric, combinations thereof, and/or other suitable materials.

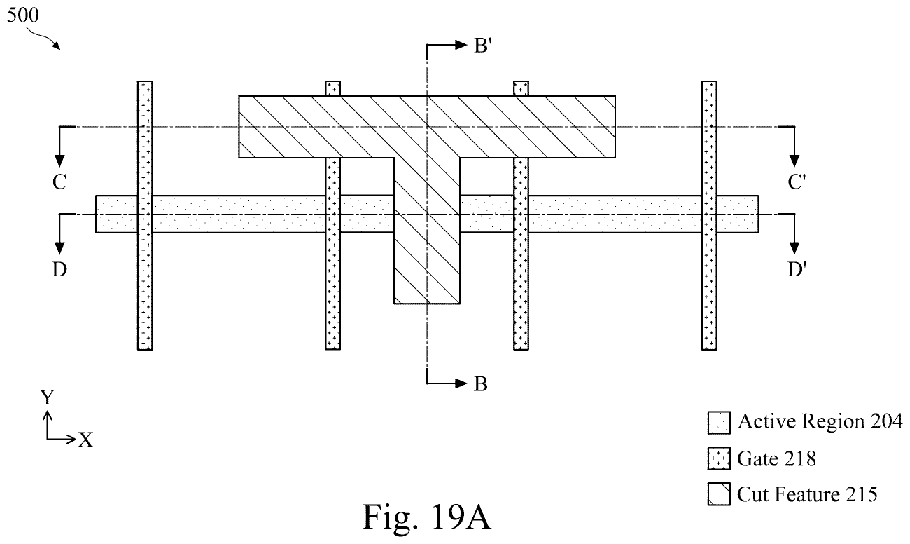

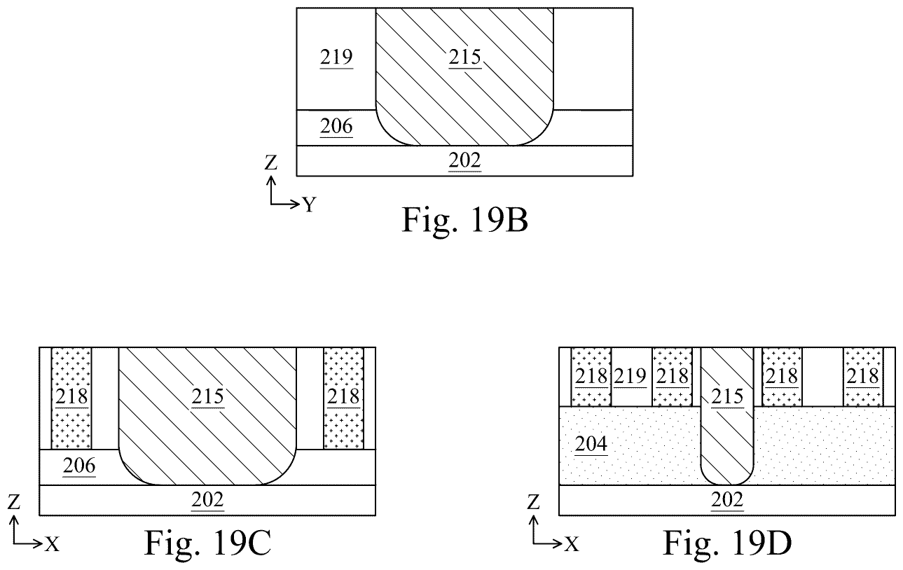

Referring now to FIGS. 19A-19D collectively, the method 1100 at operation 1110 planarizes the filled layer 615 to form a T-shaped cut feature 215 that cuts through the one or more metal gate structures 218 and the one or more active regions 204. The T-shaped cut feature 215 may be formed by performing a Chemical Mechanical Polish (CMP) to remove excess portions of the filled layer 615 over top surfaces of the ILD layer 219 and the metal gate structures 218. The resulting T-shaped cut feature 215 is a continuous dielectric feature having a single coplanar (or substantially coplanar) top surface and/or a single coplanar (or substantially coplanar) bottom surface. The T-shaped cut feature 215 has a gate-cut portion and a fin-cut portion that extend lengthwise in different directions for cutting metal gate structures 218 and cutting active regions 204, respectively.

Although not limiting, the present disclosure offers advantages for isolating between ends of active regions. One example advantage is to form dedicated cut features to cut through active regions after forming metal gates. This avoids issues of edge gates landing on uneven surfaces. This also relaxes the process margins of forming isolation structures such as shallow trench isolations. Another example advantage is to form a cut feature that simultaneously cuts through active regions and gates. This allows for simultaneous patterning and may apply to memory devices such as static-random-access memory (SRAM) devices.

One aspect of the present disclosure pertains to a device. The device includes an active region over a substrate and extending lengthwise along a first direction; an isolation structure over the substrate and surrounding the active region; first and second gate structures over the active region and extending lengthwise along a second direction perpendicular to the first direction; an interlayer dielectric (ILD) layer over the active regions; and a cut feature disposed between the first and the second gate structures and extending lengthwise along the second direction. The cut feature cuts through the ILD layer and the active region to separate the active region into two segments.

In an embodiment, the cut feature and the ILD layer have coplanar top surfaces.

In an embodiment, the cut feature and the isolation structure have coplanar bottom surfaces.

In an embodiment, the ILD layer is a first ILD layer further comprising: an etch stop layer (ESL) landing on the first ILD layer, the first and the second gate structures, and the cut feature; and a second ILD layer over the ESL. In a further embodiment, the device further includes: a gate via penetrating through the second ILD layer and the ESL to land on one of the first and the second gate structures.

In an embodiment, the device further includes: a third gate structure over the active region and extending lengthwise along the second direction. The first and the second gate structures are formed over dummy channel regions of the active region, and the third gate structure is formed over an active channel region of the active region. The active channel region forms a channel interfacing between adjacent source/drain features while the dummy channel regions do not.

In an embodiment, the active region is protruding above the isolation feature and the ILD layer is disposed on the isolation feature.

In an embodiment, the ILD layer and the cut feature include different dielectric materials.

In an embodiment, the cut feature further includes a gate-cut portion extending lengthwise along the first direction, the gate-cut portion cuts through the first and the second gate structures and separates each of the first and the second gate structures into two segments. In a further embodiment, the active region is a first active region, the device further includes: a second active region over the substrate and extending lengthwise along the first direction. The gate-cut portion is laterally disposed between the first and the second active regions. In a further embodiment, the cut feature has a T-shape from a top view.

Another aspect of the present disclosure pertains to a device. The device includes active regions over a substrate and extending lengthwise along a first direction; a shallow trench isolation (STI) structure over the substrate and formed between the active regions; gate structures over the active regions and extending lengthwise along a second direction perpendicular to the first direction; and a cut feature disposed between two gate structures and extending lengthwise along the second direction. The cut feature completely penetrates through the STI structure and a first active region of the active regions, thereby separating the first active region into two segments.

In an embodiment, the first active region includes transistor channels between source/drain features, and there is a first gate structure disposed over each of the transistor channels. The two gate structures are not disposed over the transistor channels.

In an embodiment, the two gate structures do not form transistors in the first active region.

In an embodiment, the device further includes an interlayer dielectric (ILD) layer over the active regions and surrounding the gate structures, where the cut feature also cuts through the ILD layer.

In an embodiment, the cut feature further includes a gate-cut portion extending lengthwise along the first direction, the gate-cut portion cuts through the two gate structures and separates each of the two gate structures into two segments.

Another aspect of the present disclosure pertains to a method. The method includes forming active regions over a substrate; forming an isolation structure over the substrate and between the active regions; forming metal gate structures over channel regions of the active regions; forming source/drain (S/D) features in S/D regions of the active regions; forming an interlayer dielectric (ILD) layer over the S/D features and the isolation structure; and forming a cut feature between two adjacent gate structures, the cut feature cuts through one or more of the active regions. The forming of the cut feature is performed after the forming of the metal gate structures.

In an embodiment, the forming of the active regions includes patterning a semiconductor layer to from fin active regions extending from the substrate, where the forming of the isolation structure includes depositing an isolation layer over the substrate and recessing the isolation layer to form the isolation structure, and the isolation structure has a top surface below a top surface of the fin active regions. In a further embodiment, the cut feature further cuts the ILD layer, and the cut feature has a top surface above the top surface of the fin active regions.

In an embodiment, the forming of the cut feature includes forming a T-shaped cut feature having a first segment lengthwise oriented along a first direction and a second segment lengthwise oriented along a second direction different from the first direction.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
an active region over a substrate and extending lengthwise along a first direction;
an isolation structure over the substrate and surrounding the active region;
first and second gate structures over the active region and extending lengthwise along a second direction perpendicular to the first direction;
an interlayer dielectric (ILD) layer over the active regions; and
a cut feature disposed between the first and the second gate structures and extending lengthwise along the second direction, wherein the cut feature cuts through the ILD layer and the active region to separate the active region into two segments.

2. The device of claim 1, wherein the cut feature and the ILD layer have coplanar top surfaces.

3. The device of claim 1, wherein the cut feature and the isolation structure have coplanar bottom surfaces.

4. The device of claim 1, wherein the ILD layer is a first ILD layer further comprising:
an etch stop layer (ESL) landing on the first ILD layer, the first and the second gate structures, and the cut feature; and
a second ILD layer over the ESL.

5. The device of claim 4, further comprising:
a gate via penetrating through the second ILD layer and the ESL to land on one of the first and the second gate structures.

6. The device of claim 1, further comprising:
a third gate structure over the active region and extending lengthwise along the second direction,
wherein the first and the second gate structures are formed over dummy channel regions of the active region, and the third gate structure is formed over an active channel region of the active region,
wherein the active channel region forms a channel interfacing between adjacent source/drain features while the dummy channel regions do not.

7. The device of claim 1, wherein the active region is protruding above the isolation feature and the ILD layer is disposed on the isolation feature.

8. The device of claim 1, wherein the ILD layer and the cut feature include different dielectric materials.

9. The device of claim 1, wherein the cut feature further includes a gate-cut portion extending lengthwise along the first direction, the gate-cut portion cuts through the first and the second gate structures and separates each of the first and the second gate structures into two segments.

10. The device of claim 9, wherein the active region is a first active region, further comprising:
a second active region over the substrate and extending lengthwise along the first direction, wherein the gate-cut portion is laterally disposed between the first and the second active regions.

11. The device of claim 9, wherein the cut feature has a T-shape from a top view.

12. A device, comprising:
active regions over a substrate and extending lengthwise along a first direction;
a shallow trench isolation (STI) structure over the substrate and formed between the active regions;
gate structures over the active regions and extending lengthwise along a second direction perpendicular to the first direction; and
a cut feature disposed between two gate structures and extending lengthwise along the second direction, wherein the cut feature completely penetrates through the STI structure and a first active region of the active regions, thereby separating the first active region into two segments.

13. The device of claim 12,
wherein the first active region includes transistor channels between source/drain features, and there is a first gate structure disposed over each of the transistor channels,
wherein the two gate structures are not disposed over the transistor channels.

14. The device of claim 12, wherein the two gate structures do not form transistors in the first active region.

15. The device of claim 12, further comprising an interlayer dielectric (ILD) layer over the active regions and surrounding the gate structures, wherein the cut feature also cuts through the ILD layer.

16. The device of claim 12, wherein the cut feature further includes a gate-cut portion extending lengthwise along the first direction, the gate-cut portion cuts through the two gate structures and separates each of the two gate structures into two segments.

17. A method comprising:
forming active regions over a substrate;
forming an isolation structure over the substrate and between the active regions;
forming metal gate structures over channel regions of the active regions;
forming source/drain (S/D) features in S/D regions of the active regions;
forming an interlayer dielectric (ILD) layer over the S/D features and the isolation structure; and
forming a cut feature between two adjacent gate structures, the cut feature cuts through one or more of the active regions,
wherein the forming of the cut feature is performed after the forming of the metal gate structures.

18. The method of claim 17,
wherein the forming of the active regions includes patterning a semiconductor layer to from fin active regions extending from the substrate,
wherein the forming of the isolation structure includes:
depositing an isolation layer over the substrate, and
recessing the isolation layer to form the isolation structure, and the isolation structure has a top surface below a top surface of the fin active regions.

19. The method of claim 18, wherein the cut feature further cuts the ILD layer, and the cut feature has a top surface above the top surface of the fin active regions.

20. The method of claim 17, wherein the forming of the cut feature includes forming a T-shaped cut feature having a first segment lengthwise oriented along a first direction and a second segment lengthwise oriented along a second direction different from the first direction.
